(19) United States
(12) Patent Application Publication
(10) Pub. No.: US 2014/0084790 A1
(43) Pub. Date: Mar. 27, 2014

(54) ELECTROMAGNETIC INTERFERENCE FILTER, AND POWER SUPPLY APPARATUS AND DISPLAY APPARATUS INCLUDING THE SAME

(71) Applicant: SAMSUNG ELECTRO-MECHANICS CO., LTD., Suwon-si (KR)

(72) Inventors: Jae Sun WON, Suwon-si (KR); Jong Hae KIM, Suwon-si (KR); Seung Wan YU, Suwon-si (KR); Myung Chul LEE, Suwon-si (KR); Seung Ho HAN, Suwon-si (KR); Hyeong Kyu JEONG, Suwon-si (KR); Hwa Hun CHIN, Suwon-si (KR)

(73) Assignee: SAMSUNG ELECTRO-MECHANICS CO., LTD., Suwon-si (KR)

(21) Appl. No.: 13/725,469

(22) Filed: Dec. 21, 2012

(30) Foreign Application Priority Data
Sep. 26, 2012 (KR) 10-2012-0107392

(51) Int. Cl. H05K 9/00; H02M 1/12; H05B 37/02

(52) U.S. Cl. CPC H05K 9/00; H05B 37/02; H02M 1/12
USPC 315/85; 363/44; 336/65

(57) ABSTRACT

There are provided an electromagnetic interference filter for removing common mode electromagnetic interference, in which electromagnetic interference of a low frequency band and a high frequency band is removed in a single filter because of a wide block frequency band, a power supply apparatus including the electromagnetic interference filter, and a display apparatus including the electromagnetic interference filter. The electromagnetic interference filter includes a core part including at least two legs electromagnetically coupled and forming a closed magnetic circuit; a coil part including first and second rectangular copper wires respectively wound in a single layer around the at least two legs and removing common mode electromagnetic interference included in power transferred from a power line; and a support part having a mounting area in which the core part having the coil part wound therearound is mounted.

### CROSS-REFERENCE TO RELATED APPLICATIONS

This application claims the priority of Korean Patent Application No. 10-2012-0107392 filed on Sep. 26, 2012, in the Korean Intellectual Property Office, the disclosure of which is incorporated herein by reference.

### BACKGROUND OF THE INVENTION

1. Field of the Invention

The present invention relates to a filter for removing electromagnetic interference, and more particularly to an electromagnetic interference filter for removing common mode electromagnetic interference, a power supply apparatus including the electromagnetic interference filter, and a display apparatus including the electromagnetic interference filter.

2. Description of the Related Art

In general, a power supply apparatus for supplying driving power necessary for driving an electronic apparatus satisfying various user requirements is inevitably employed in the electronic apparatus.

Such an electronic apparatus performs a process of converting commercially available alternating current (AC) power to driving power. During the process, electromagnetic interference may occur. In particular, during a switching operation for power factor compensation, a very high amount of electromagnetic interference may occur.

To remove the above-described electromagnetic interference, an electromagnetic interference filter may be employed in a power input terminal to which the AC power is input. The electromagnetic interference may largely be divided into conducted emissions and radiated emissions. Further, the conducted emissions and the radiated emissions may be classified as differential mode electromagnetic interference and common mode electromagnetic interference respectively.

To remove the above-described common mode electromagnetic interference, as disclosed in the following prior art document, common mode choke coils are employed in live neutral ends of power input lines, and at least one differential mode choke coil is separately employed to remove the electromagnetic interference of the differential mode.

The common mode choke coil includes a common mode choke coil of a low frequency band and a common mode choke coil of a high frequency band to remove electromagnetic interference of a corresponding frequency band and obtains a wide frequency band to remove the electromagnetic interference. However, a volume of the choke coil used to remove the above-described electromagnetic interference may be increased, and the increase in volume is disadvantageous in terms of consumer demand for lightweight, slim, compact apparatuses.

Further, conventional electromagnetic interference filter is formed by combining a donut-shaped core with an insulating bobbin having two coils wound therearound in opposite directions, thereby disabling automatic production, slowing production speeds and increasing manufacturing costs accordingly.

Likewise, technological research into slimming an overall size of a product appearance is actively being carried out in the display industry, and thus, various flat panel display apparatuses such as liquid crystal displays (LCDs), plasma display panels (PDPs), organic light emitting diodes (OLEDs), etc. have been developed.

As display apparatuses have been slimmed, a space between a back cover and a power supply apparatus thereof has been narrowed in recent display apparatuses. Thus, compactness and slimness in an electromagnetic interference filter mounted in the power supply apparatus are also required.

### RELATED ART DOCUMENT

(Patent Document 1) Korean Patent Laid-Open Publication No. 10-2012-0070228

### SUMMARY OF THE INVENTION

An aspect of the present invention provides an electromagnetic interference filter for removing common mode electromagnetic interference in which electromagnetic interference of a low frequency band and a high frequency band is removed in a single filter because of a wide block frequency band, a power supply apparatus including the electromagnetic interference filter, and a display apparatus including the electromagnetic interference filter.

According to an aspect of the present invention, there is provided an electromagnetic interference filter including: a core part including at least two legs electromagnetically coupled and forming a closed magnetic circuit; a coil part including first and second rectangular copper wires respectively wound in a single layer around the at least two legs and removing common mode electromagnetic interference included in power transferred from a power line; and a support part having a mounting area in which the core part having the coil part wound therearound is mounted.

Surfaces of the at least two legs in a surface of the core part may be insulation-coated.

The surface of the core part may be insulation-coated.

Widths of the respective first and second rectangular copper wires may be greater than thicknesses and lengths thereof.

One end of the first rectangular copper wire may be electrically connected to alive end of the power line, and one end of the second rectangular copper wire may be electrically connected to a neutral end of the power line.

The first and second rectangular copper wires may be wound in opposite directions.

The electromagnetic interference filter may further include: a capacitor group including first and second Y capacitors connected to each other in series between the live end and the neutral end of the power line, and a first X capacitor connected to the first and second Y capacitors in parallel between the live end and the neutral end of the power line.

According to another aspect of the present invention, there is provided a power supply apparatus including: an electromagnetic interference filter including a core part including at least two legs electromagnetically coupled and forming a closed magnetic circuit; a coil part including first and second rectangular copper wires respectively wound in a single layer around the at least two legs and removing common mode electromagnetic interference included in power transferred from a power line; and a support part having a mounting area in which the core part having the coil part wound therearound is mounted; and a power converting unit switching the power from which the electromagnetic interference is removed by the electromagnetic interference filter, and converting the power into driving power having a previously set voltage level.

The power supply apparatus may further include: a rectifying unit rectifying and smoothing the power from which the electromagnetic interference is removed by the electromagnetic interference filter. The power supply apparatus may further include: a power factor correction unit correcting a power factor of the power from which the electromagnetic interference is removed by the electromagnetic interference filter.

According to another aspect of the present invention, there is provided a display apparatus including: a panel; a backlight unit disposed on a rear surface of the panel and emitting light; a printed circuit board disposed on a rear surface of the backlight unit; a power supply apparatus formed on the printed circuit board and supplying driving power to the backlight unit; and a back cover coupled to the backlight unit and covering the printed circuit board and a transformer, wherein the power supply apparatus includes an electromagnetic interference filter including a core part including at least two legs electromagnetically coupled and forming a closed magnetic circuit; a coil part including first and second rectangular copper wires respectively wound in a single layer around the at least two legs and removing common mode electromagnetic interference included in power transferred from a power line; and a support part having a mounting area in which the core part having the coil part wound therearound is mounted; and a power converting unit switching the power from which the electromagnetic interference is removed by the electromagnetic interference filter, and converting the power into driving power having a previously set voltage level.

The backlight unit may include at least one light emitting diode.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A and 1B are an exploded perspective view and an assembled view of an electromagnetic interference filter according to an embodiment of the present invention;

FIGS. 2A and 2B are concept views of a coil winding of the electromagnetic interference filter according to the embodiment of the present invention;

FIG. 3 is an assembled view of an electromagnetic interference filter according to another embodiment of the present invention;

FIG. 4 is a graph showing impedance characteristics in frequency bands according to the related art and the present invention;

FIG. 5 is a schematic circuit view of the electromagnetic interference filter according to the embodiment of the present invention;

FIGS. 6A and 6B are graphs showing electromagnetic interference measurements according to the related art and the present invention;

FIGS. 7 and 8 are schematic block views respectively showing a power supply apparatus including an electromagnetic interference filter according to an embodiment of the present invention; and

FIG. 9 is a schematic configuration view of a display apparatus including an electromagnetic interference filter according to an embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

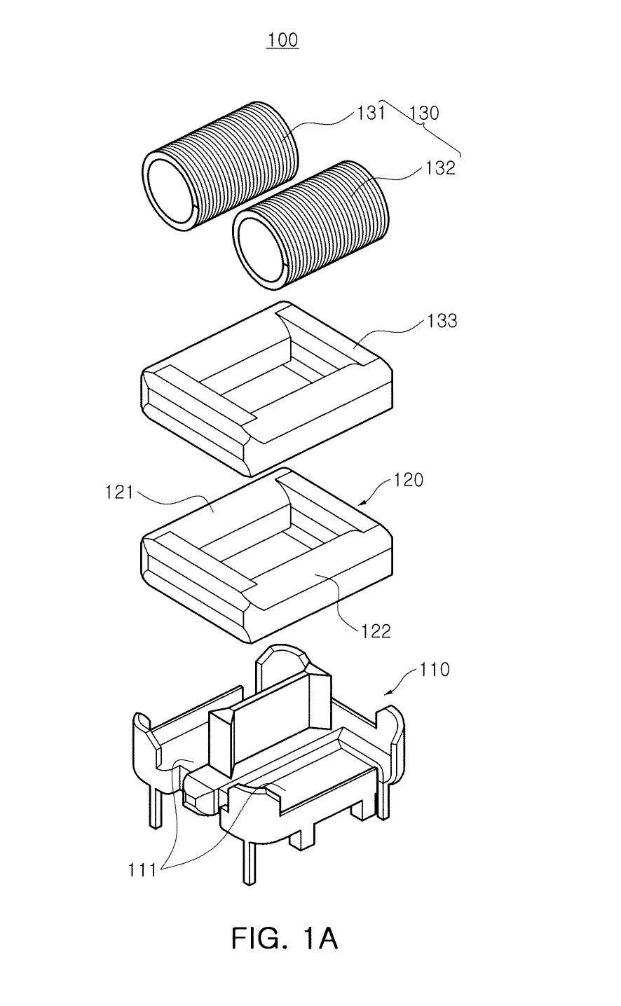

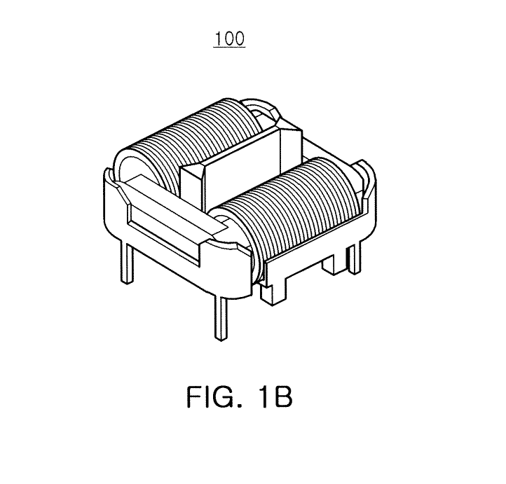

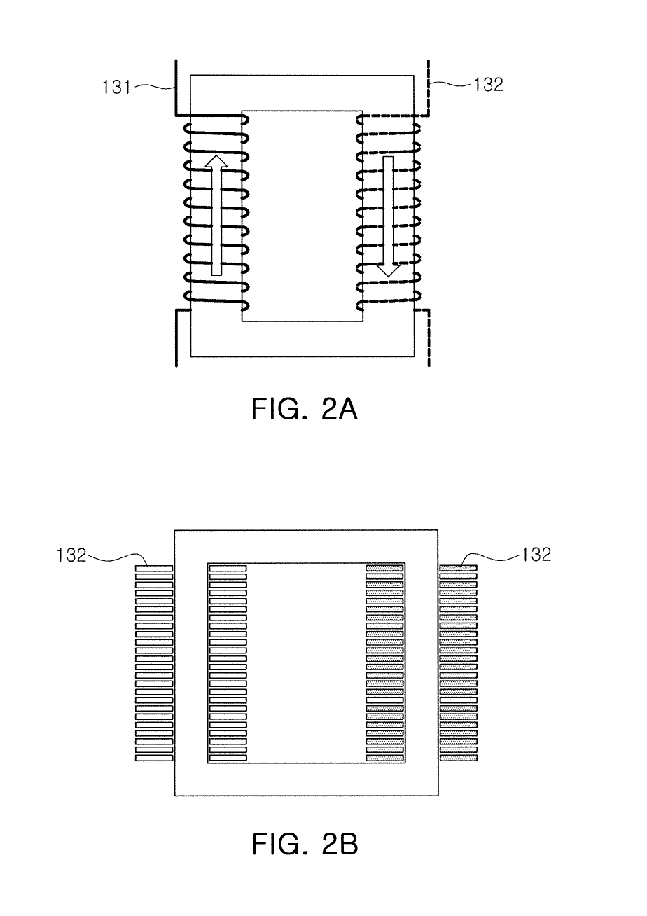

FIGS. 1A and 1B are an exploded perspective view and an assembled view of an electromagnetic interference filter according to an embodiment of the present invention. FIGS. 2A and 2B are concept views of a coil winding of the electromagnetic interference filter according to the embodiment of the present invention. FIG. 3 is an assembled view of an electromagnetic interference filter according to another embodiment of the present invention.

Referring to FIGS. 2A and 2B, along with FIGS. 1A and 1B, an electromagnetic interference filter 100 according to an embodiment of the present invention may include a choke coil including a support part 110, a core part 120, and a coil part 130.

The support part 110 may be formed of an insulator and include a mounting area 111 accommodating the core part 120 therein and enclosing at least a portion of the core part 120.

The core part 120 may include at least two legs 121 and 122 formed of a magnetic material. The at least two legs 121 and 122 may be electromagnetically coupled to each other by electromagnetic force to form a closed magnetic circuit. The core part 120 may be a rectangular core; however, the present invention is not limited thereto. The core part 120 may be formed in various manners, such as a UU core coupled shape, a CI core coupled shape, or the like. Coils may be wound around the at least two legs 121 and 122. An insulating coating part 123 may be formed on surfaces of the at least two legs 121 and 122 and may be formed on the entire surface of the core part 120, in order to provide electrical insulation.

The coil part 130 may include first and second rectangular copper wires 131 and 132 wound in opposite directions.

The first and second rectangular copper wires 131 and 132 have rectangular cross-sections, other than circular cross-sections. Accordingly, when a coil is wound, the rectangular copper wire may be more tightly wound than a copper wire having a circular cross-section. The first and second rectangular copper wires 131 and 132 may be wound around the first and second legs 121 and 122 of the core part 120, respectively, and may be wound in a single layer around the first and second legs 121 and 122. Accordingly, parasitic capacitance generated by the wound rectangular copper wires may be reduced.

The parasitic capacitance is inversely proportional to a resonance frequency, and thus the reduction in the parasitic capacitance causes an increase in the resonance frequency, thereby increasing a block frequency band of the electromagnetic interference filter.

Meanwhile, as shown in FIG. 1B, the choke coil included in the electromagnetic interference filter according to the embodiment of the present invention may be a horizontal type choke coil in which the core part 120 and the coil part 130 are laid down to be mounted in the support part 110, and as shown in FIG. 3, may be a vertical type choke coil in which the core part 120 and the coil part 130 are in a standing position to be mounted in the support part 110.

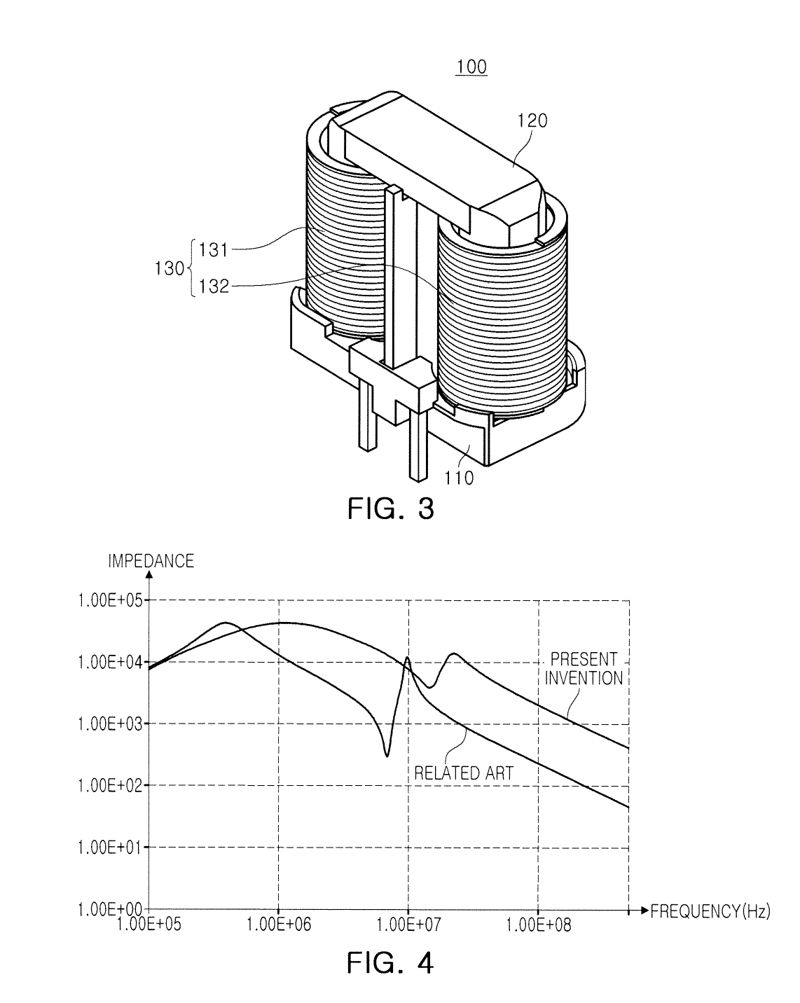

FIG. 4 is a graph showing impedance characteristics in frequency bands according to the related art and the present invention.

Referring to FIG. 4, in the case of a choke coil employed in a conventional electromagnetic interference filter, impedance is high in a low frequency band while impedance is low in a high frequency band. Accordingly, the electromagnetic interference filter needs to separately include a choke coil for removing an electro-magnetic interference in the high frequency band. However, in the choke coil of the electromagnetic interference filter according to the embodiment of the present invention, parasitic capacitance is reduced and thus, impedance is high in the high frequency band. Accordingly, electromagnetic interference can be easily removed in a band range from the low frequency band to the high frequency band.

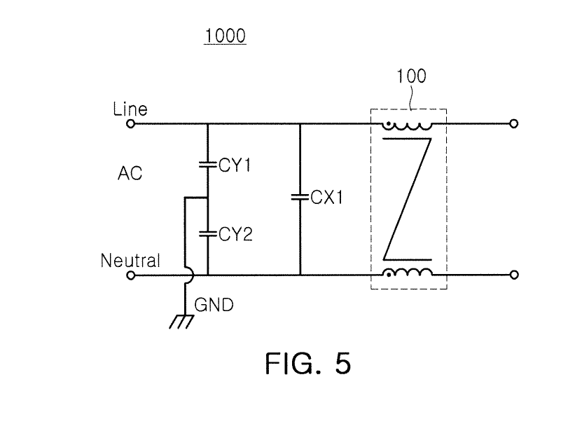

FIG. 5 is a schematic circuit view of the electromagnetic interference filter according to the embodiment of the present invention.

Referring to FIG. 5, the electromagnetic interference filter according to the embodiment of the present invention may further include a capacitor group in addition to the choke coil shown in FIGS. 1A through 3.

The capacitor group may include first and second Y capacitors Cy1, Cy2 and a first X capacitor Cx1.

The first and second Y capacitors Cy1, Cy2 may be connected to each other in series between a live end L and a neutral end N of a power line. A connection point of the first and second Y capacitors Cy1, Cy2 may be connected to a ground. The first and second Y capacitors Cy1, Cy2 may remove common mode electromagnetic interference from power passing through the power line.

The first X capacitor Cx1 may be connected to the first and second Y capacitors Cy1, Cy2 in parallel, between the live end L and the neutral end N of the power line, and may remove differential mode electromagnetic interference from the power passing through the power line.

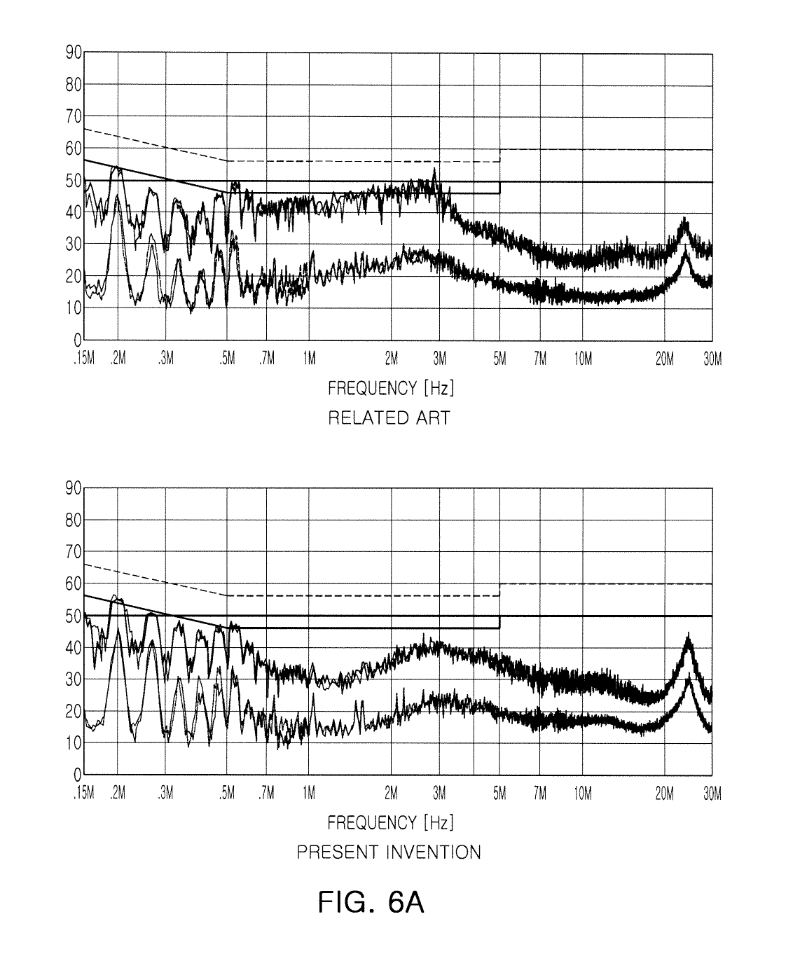

FIGS. 6A and 6B are graphs showing electromagnetic interference measurements according to the related art and the present invention.

An upper graph of the graphs shown in FIGS. 6A and 6B illustrates an electromagnetic interference measurement of an electromagnetic interference filter according to the related art, and a lower graph thereof illustrates an electromagnetic interference measurement of the electromagnetic interference filter according to the present invention.

FIG. 6A is the graph showing a conducted emission measurement of the electromagnetic interference, and FIG. 6B is the graph showing a radiated emission measurement of the electromagnetic interference (a green (blue) line and a red line indicate a peak value and an average value of the electromagnetic interference).

Referring to FIG. 6A, even in the case in which the electromagnetic interference filter according to the present invention employs a single choke coil, a margin of about 15 dB is higher in a frequency band of 0.5 MHz-5 MHz as compared to the related art, and referring to FIG. 6B, a margin of about 10 dB is higher in a frequency band of 30 MHz-200 MHz as compared to the related art.

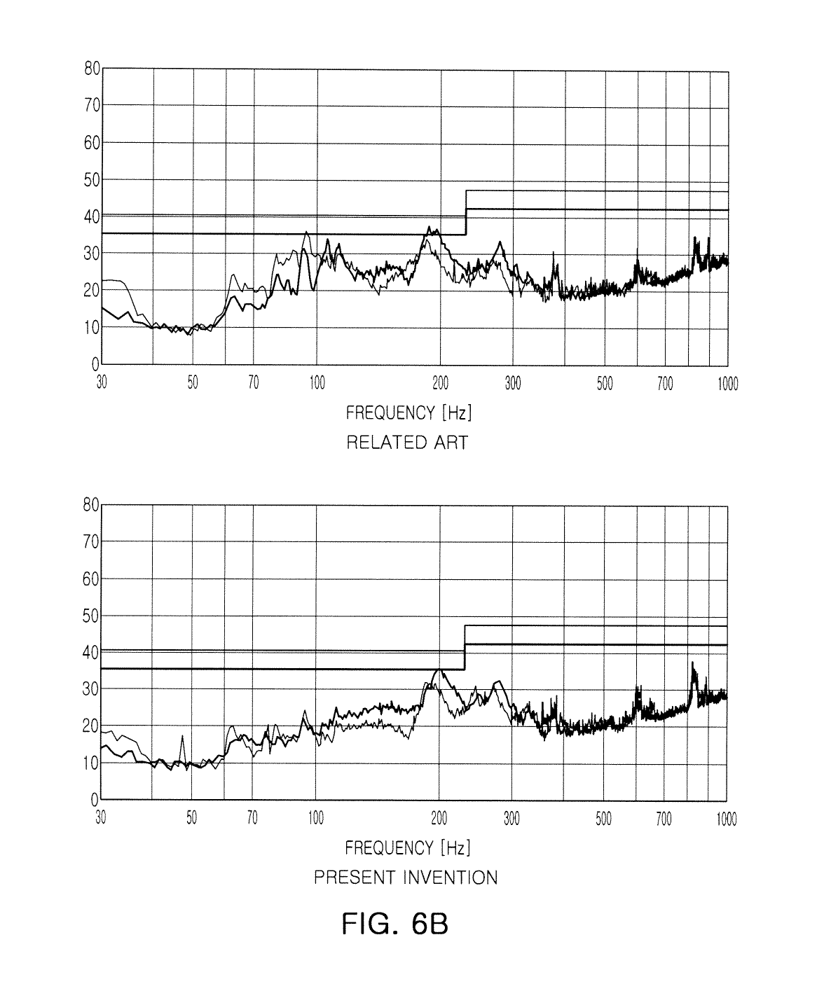

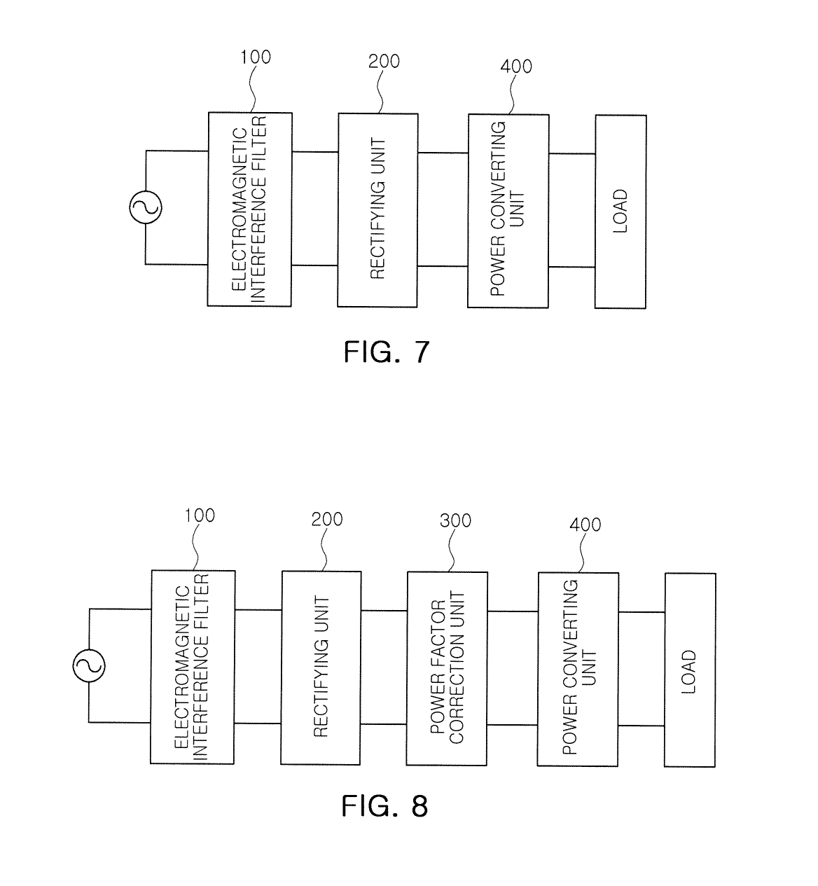

FIGS. 7 and 8 are schematic block views respectively showing a power supply apparatus including an electromagnetic interference filter according to an embodiment of the present invention.

A power supply apparatus 1000 according to an embodiment of the present invention may include the electromagnetic interference filter 100, a rectifying unit 200, and a power converting unit 400, as shown in FIG. 7, and may include the electromagnetic interference filter 100, the rectifying unit 200, a power factor correction unit 300, and the power converting unit 400, as shown in FIG. 8.

The electromagnetic interference filter 100 may be formed between a live end and a neutral end of a power line to which commercially available AC power is supplied to thereby remove common mode electromagnetic interference and differential mode electromagnetic interference included in the power transferred through the power line.

The rectifying unit 200 may rectify and smooth the power from which electromagnetic interference has been removed by the electromagnetic interference filter 100.

The power factor correction unit 300 may switch the power rectified by the rectifying unit 200 and adjust a phase difference between voltage and current of the power to correct a power factor thereof.

The power converting unit 400 may convert the power of which power factor is corrected by the power factor correction unit 300 into driving power having a previously set voltage level and supply the driving power to a load.

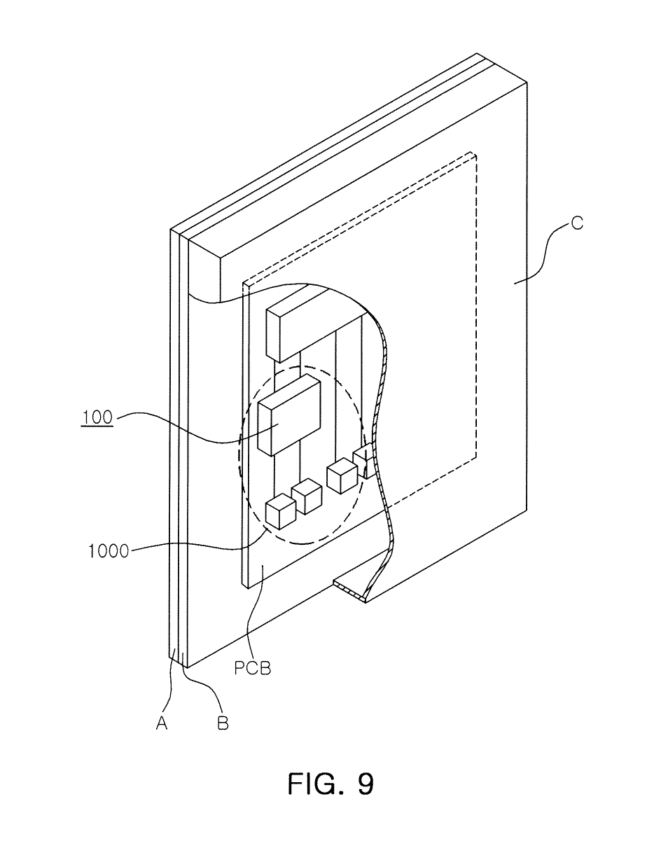

FIG. 9 is a schematic configuration view of a display apparatus including an electromagnetic interference filter according to an embodiment of the present invention.

Referring to FIG. 9, a display apparatus including a power supply apparatus according to an embodiment of the present invention may include a panel A, a backlight unit B supporting the panel A and including a light source, a printed circuit board (PCB) supplying power to the light source included in the backlight unit B, the electromagnetic interference filter 100 according the embodiment of the present invention removing electromagnetic interference of the power moving from the printed circuit board (PCB), the power supply apparatus 1000 including the electromagnetic interference filter 100 and supplying driving power to the backlight unit B, and a back cover C coupled to the backlight unit B.

The panel A according to the embodiment of the present invention may be an LCD panel; however, the present invention is not limited thereto.

For example, in a case in which the panel A is an LCD panel, the backlight unit B may include a light guide panel, a plurality of sheets, a lamp reflector, and a mold frame (or a support main) as well as a lamp as the light source.

In this regard, the plurality of sheets may include a reflection sheet, a diffusion sheet, a prism sheet, and a protect sheet.

Meanwhile, a light emitting diode (LED) may be used as the light source of the backlight unit B according to the embodiment of the present invention. The printed circuit board (PCB) may be provided with the electromagnetic interference filter 100 and the power supply apparatus 1000 such as a power element, a power component, a power-related circuit for supplying power to the display apparatus according to the embodiment of the present invention.

As set forth above, according to embodiments of the invention, a winding of the choke coil configuring the electromagnetic interference filter is formed as a single layer rectangular copper wire, and thus a parasitic capacitance is reduced to remove electromagnetic interference of a high frequency band and a low frequency band by using a single choke coil, thereby reducing manufacturing costs of the electromagnetic interference filter and reducing a volume thereof.

While the present invention has been shown and described in connection with the embodiments, it will be apparent to those skilled in the art that modifications and variations can be made without departing from the spirit and scope of the invention as defined by the appended claims.

What is claimed is:

1. An electromagnetic interference filter comprising:
a core part including at least two legs electromagnetically coupled and forming a closed magnetic circuit;
a coil part including first and second rectangular copper wires respectively wound in a single layer around the at least two legs and removing common mode electromagnetic interference included in power transferred from a power line; and
a support part having a mounting area in which the core part having the coil part wound therearound is mounted.

2. The electromagnetic interference filter of claim 1, wherein surfaces of the at least two legs in a surface of the core part are insulation-coated.

3. The electromagnetic interference filter of claim 2, wherein the surface of the core part is insulation-coated.

4. The electromagnetic interference filter of claim 1, wherein widths of the respective first and second rectangular copper wires are greater than thicknesses and lengths thereof.

5. The electromagnetic interference filter of claim 1, wherein one end of the first rectangular copper wire is electrically connected to a live end of the power line, and one end of the second rectangular copper wire is electrically connected to a neutral end of the power line.

6. The electromagnetic interference filter of claim 1, wherein the first and second rectangular copper wires are wound in opposite directions.

7. The electromagnetic interference filter of claim 5, further comprising a capacitor group including first and second Y capacitors connected to each other in series between the live end and the neutral end of the power line, and a first X capacitor connected to the first and second Y capacitors in parallel between the live end and the neutral end of the power line.

8. A power supply apparatus comprising:
an electromagnetic interference filter including a core part including at least two legs electromagnetically coupled and forming a closed magnetic circuit; a coil part including first and second rectangular copper wires respectively wound in a single layer around the at least two legs and removing common mode electromagnetic interference included in power transferred from a power line; and a support part having a mounting area in which the core part having the coil part wound therearound is mounted; and
a power converting unit switching the power from which the electromagnetic interference is removed by the electromagnetic interference filter, and converting the power into driving power having a previously set voltage level.

9. The power supply apparatus of claim 8, wherein surfaces of the at least two legs in a surface of the core part are insulation-coated.

10. The power supply apparatus of claim 9, wherein the surface of the core part is insulation-coated.

11. The power supply apparatus of claim 8, wherein widths of the respective first and second rectangular copper wires are greater than thicknesses and lengths thereof.

12. The power supply apparatus of claim 8, wherein one end of the first rectangular copper wire is electrically connected to a live end of the power line, and one end of the second rectangular copper wire is electrically connected to a neutral end of the power line.

13. The power supply apparatus of claim 8, wherein the first and second rectangular copper wires are wound in opposite directions.

14. The power supply apparatus of claim 12, further comprising a capacitor group including first and second Y capacitors connected to each other in series between the live end and the neutral end of the power line, and a first X capacitor connected to the first and second Y capacitors in parallel between the live end and the neutral end of the power line.

15. The power supply apparatus of claim 8, further comprising a rectifying unit rectifying and smoothing the power from which the electromagnetic interference is removed by the electromagnetic interference filter.

16. The power supply apparatus of claim 8, further comprising a power factor correction unit correcting a power factor of the power from which the electromagnetic interference is removed by the electromagnetic interference filter.

17. A display apparatus comprising:
a panel;
a backlight unit disposed on a rear surface of the panel and emitting light;
a printed circuit board disposed on a rear surface of the backlight unit;
a power supply apparatus formed on the printed circuit board and supplying driving power to the backlight unit; and
a back cover coupled to the backlight unit and covering the printed circuit board and a transformer,
wherein the power supply apparatus includes an electromagnetic interference filter including a core part including at least two legs electromagnetically coupled and forming a closed magnetic circuit; a coil part including first and second rectangular copper wires respectively wound in a single layer around the at least two legs and removing common mode electromagnetic interference included in power transferred from a power line; and a support part having a mounting area in which the core part having the coil part wound therearound is mounted; and
a power converting unit switching the power from which the electromagnetic interference is removed by the electromagnetic interference filter, and converting the power into driving power having a previously set voltage level.

18. The display apparatus of claim 17, wherein surfaces of the at least two legs in a surface of the core part are insulation-coated.

19. The display apparatus of claim 18, wherein the surface of the core part is insulation-coated.

20. The display apparatus of claim 17, wherein widths of the respective first and second rectangular copper wires are greater than thicknesses and lengths thereof.

21. The display apparatus of claim 17, wherein one end of the first rectangular copper wire is electrically connected to a live end of the power line, and one end of the second rectangular copper wire is electrically connected to a neutral end of the power line.

22. The display apparatus of claim 17, wherein the first and second rectangular copper wires are wound in opposite directions.

23. The display apparatus of claim 21, further comprising a capacitor group including first and second Y capacitors connected to each other in series between the live end and the neutral end of the power line, and a first X capacitor connected to the first and second Y capacitors in parallel between the live end and the neutral end of the power line.

24. The display apparatus of claim 17, further comprising a rectifying unit rectifying and smoothing the power from which the electromagnetic interference is removed by the electromagnetic interference filter.

25. The display apparatus of claim 17, further comprising a power factor correction unit correcting a power factor of the power from which the electromagnetic interference is removed by the electromagnetic interference filter.

26. The display apparatus of claim 17, wherein the backlight unit includes at least one light emitting diode.
